(19) United States
(12) Patent Application Publication
(10) Pub. No.: US 2023/0136874 A1
(43) Pub. Date: May 4, 2023

(54) DISPLAY PANEL

(71) Applicant: KunShan Go-Visionox Opto-Electronics Co., Ltd., Kunshan (CN)

(72) Inventors: Zhimin YAN, Kunshan (CN); Huihui MENG, Kunshan (CN); Shupeng WANG, Kunshan (CN); Yawei LIU, Kunshan (CN)

(73) Assignee: KunShan Go-Visionox Opto-Electronics Co., Ltd., Kunshan (CN)

(21) Appl. No.: 18/147,191

(22) Filed: Dec. 28, 2022

Related U.S. Application Data
(63) Continuation of application No. PCT/CN2021/104547, filed on Jul. 5, 2021.

(30) Foreign Application Priority Data
Sep. 9, 2020 (CN) 202010941775.4

(51) Int. Cl. H10K 59/80; H10K 59/12

(52) U.S. Cl. CPC H10K 59/8731; H10K 59/1201

(57) ABSTRACT

Disclosed is a display panel, which solves the problem that water and oxygen easily intrude from the edge of the isolation layer in the prior art. The display panel includes an array substrate, including a display area and a frame area surrounding the display area; a protrusion located in the frame area, the protrusion comprising a first side wall on a side close to the display area and a second side wall on a side away from the display area, at least one of the first side wall and the second side wall comprising a concave area; and an isolation layer stacked on one side of the array substrate and the protrusion, the protrusion being located in an orthographic projection of the isolation layer on the array substrate.

### CROSS-REFERENCE TO RELATED APPLICATIONS

The application is a continuation of International Application PCT/CN2021/104547, filed on Jul. 5, 2021, which claims priority to Chinese Patent Application CN202010941775.4, filed on Sep. 9, 2020, the entire contents of which are incorporated herein by reference.

### TECHNICAL FIELD

The present application relates to the field of display technology, and in particular, to a display panel.

### BACKGROUND

An existing display panel usually includes an isolation layer disposed between an organic light-emitting structure layer and a encapsulation structure. Since the edge of the isolation layer is exposed to the air, which makes water and oxygen easily intrude from the edge, the reliability of the encapsulation is affected.

### SUMMARY

In view of this, the embodiments of the present application provide a display panel to solve the problem in the prior art that the edge of the isolation layer is easy to be intruded by water and oxygen therefrom.

The embodiments of the present application provide a display panel, including: an array substrate comprising a display area and a frame area surrounding the display area; a protrusion located in the frame area, the protrusion comprising a first side wall on a side close to the display area and a second side wall on a side away from the display area, at least one of the first side wall and the second side wall comprising a concave area; and an isolation layer stacked on one side of the array substrate and the protrusion, the protrusion being located in an orthographic projection of the isolation layer on the array substrate.

According to the display panel provided by the embodiments of the present application, the protrusions are provided, and a concave area is formed on the first side wall and/or the second side wall of the protrusion. In this way, since the concave area is not in the deposition direction, the film needs to be deposited by diffusion of ions or atoms, resulting in a thinning or even disconnection of the film thickness of the subsequently prepared isolation layer in the concave area. In addition, since the reduced thickness of the isolation layer can be effectively suppressed the intrusion of water and oxygen. Therefore, the isolation layer in the concave area can inhibit the intrusion of water and oxygen, thereby reducing the probability of water and oxygen intrusion through the edge of the isolation layer as a whole and improving the reliability of the encapsulation. At the same time, by providing the protrusions, the length of the isolation layer is extended, that is, the invasion path of water and oxygen is extended, thereby further reducing the probability of water and oxygen intrusion and improving the reliability of the encapsulation.

### BRIEF DESCRIPTION OF DRAWINGS

FIG. 1 is a schematic structural diagram of a display panel according to an embodiment of the present application.

FIG. 2 is a schematic structural diagram of a display panel according to another embodiment of the present application.

FIG. 3 is a schematic structural diagram of a protrusion provided by an embodiment of the present application.

FIG. 4 is a schematic diagram of a manufacturing process of a protrusion provided by an embodiment of the present application.

FIG. 5 is a schematic diagram of a manufacturing process of a protrusion according to another embodiment of the present application.

FIG. 6 is a structural block diagram of a display device according to an embodiment of the present application.

### DETAILED DESCRIPTION OF THE EMBODIMENTS

The technical solutions in the embodiments of the present application will be clearly and completely described below with reference to the drawings in the embodiments of the present application. Obviously, the described embodiments are only a part of the embodiments of the present application, but not all of the embodiments. Based on the embodiments in this application, all other embodiments obtained by those of ordinary skill in the art without creative efforts shall fall within the protection scope of this application.

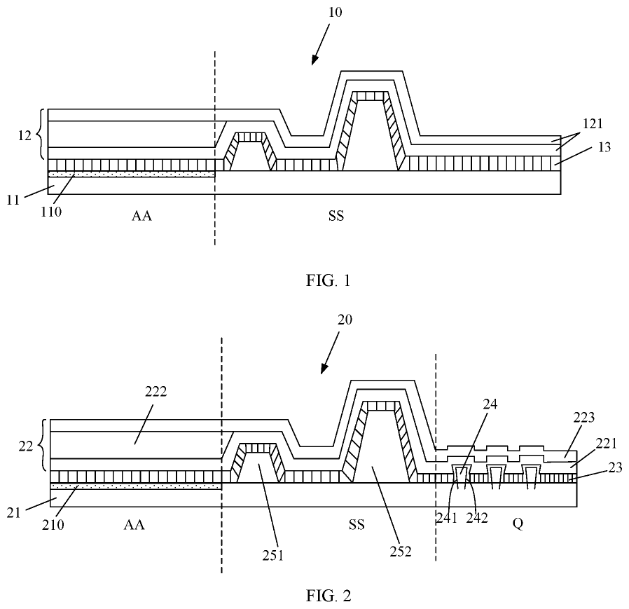

FIG. 1 is a schematic structural diagram of a display panel according to an embodiment of the present application. As shown in FIG. 1, the display panel 10 includes an isolation layer 13 disposed between an organic light-emitting structure layer 110 and a encapsulation structure 12. The isolation layer 13 can block plasma generated in the process of preparing the encapsulation structure 12, so as to prevent the plasma from adversely affecting the organic light-emitting structure layer 110, thereby affecting the display effect. The preparation process of the isolation layer 13 uses the same mask as the inorganic encapsulation layer 121 in the encapsulation structure 12. Therefore, as shown in FIG. 1, the isolation layer 13 covers a display area AA where the organic light-emitting structure layer 110 is located, and further extends to a frame area SS of an array substrate 11. The encapsulation structure 12 does not cover a sidewall of the isolation layer 13, and the sidewall of the isolation layer 13 is directly exposed to the air. In this case, since a compactness of the isolation layer 13 is lower than a compactness of the inorganic encapsulation layer 121 in the encapsulation structure 12, water and oxygen in the air are likely to intrude inward from the sidewall of the isolation layer 13, reducing the reliability of the encapsulation.

In view of this, referring to FIG. 2, another embodiment of the present application provides a display panel. As shown in FIG. 2, a display panel 20 includes an array substrate 21, an isolation layer 23 and a protrusion 24. Specifically, the array substrate 21 includes a display area AA and a frame area SS surrounding the display area AA. The protrusion 24 is located in the frame area SS and includes a first side wall 241 on a side close to the display area AA and a second side wall 242 on a side away from the display area AA. At least one of the first side wall 241 and the second side wall 242 includes a concave area. The isolation layer 23 is stacked on one side of the array substrate 21 and the protrusion 24, and the protrusion 24 is located in an orthographic projection of the isolation layer 23 on the array substrate 21.

The array substrate 21 includes a base substrate and a thin-film transistor (TFT) array formed on the base substrate. The base substrate may be made of any one of a glass material, a metal material, or a plastic material including polyethylene terephthalate, polyethylene naphthalate (PEN), or polyimide. The TFT array can be directly disposed on the base substrate. It should be understood that, in addition to the thin film transistors, the TFT array may also include film layers such as a planarization layer and a passivation layer, which are not limited herein.

The isolation layer 23 may be a single film layer or may be a composite film layer composed of a plurality of film layers stacked in sequence. The isolation layer 23 can be prepared by using any inorganic material with water and oxygen barrier function. In one embodiment, the material of the isolation layer 23 is silicon oxide.

The array substrate 21 is divided into a display area AA and a frame area SS surrounding the display area AA. The display area AA is provided with an organic light-emitting structure layer 210 for emitting light, the frame area SS is provided with the protrusion 24, and the barrier layer 23 is stacked on the array substrate 21, covering the organic light-emitting structure layer 210 and the protrusion 24.

The organic light-emitting structure layer 210 includes a pixel defining layer, a first electrode layer, a light-emitting layer and a second electrode layer which are sequentially provided on the array substrate 21. The pixel defining layer is provided with an opening to expose the first electrode layer. The light-emitting layer is disposed in the opening of the pixel defining layer and on the exposed first electrode layer. The second electrode layer covers the light-emitting layer. The light-emitting layer may include sub-pixels emitting red light, sub-pixels emitting green light, or sub-pixels emitting blue light. In one embodiment, the first electrode layer is an anode, and the second electrode layer is a cathode.

In this embodiment, the height of the protrusion 24 protruding from the surface of the array substrate on which the protrusions are disposed is greater than or equal to 1 micrometer and less than or equal to 10 micrometers. The isolation layer 23 includes a silicon oxide layer. The thickness of the silicon oxide layer is greater than or equal to 5 angstroms and less than or equal to 2000 angstroms. Considering the precision of the existing film forming device, the silicon oxide layer is easier to be prepared when the thickness of the silicon oxide layer is 600 angstroms.

The concave area on the first side wall 241 and/or the second side wall 242 of the protrusion 24 refers to the area formed on the first side wall 241 and/or the second side wall 242 that is protruded around and recessed in the middle, that is, the center is recessed toward the interior of the protrusion 24 compared to the periphery.

In this case, when the isolation layer 23 is prepared by chemical vapor deposition (CVD) or atomic layer deposition (ALD), since the concave area of the protrusion 24 is not in the deposition direction, the film needs to be deposited by the diffusion of ions or atoms, resulting in the subsequent prepared isolation layer 23 being thinned or even disconnected in the concave area. In addition, since the thickness of the isolation layer 23 is thinned, it is beneficial to inhibit the intrusion of water and oxygen, so the isolation layer 23 in the concave area has a higher ability of water and oxygen inhibition, thereby reducing the probability of water and oxygen intruding inward through the edge of the isolation layer, and improving the reliability of the encapsulation. At the same time, by providing the protrusion 24, the length of the isolation layer 23 is extended, that is, the water and oxygen intrusion path is extended, thereby further reducing the probability of water and oxygen intrusion and improving the reliability of encapsulation.

It should be noted that, the display panel 20 may include a number of protrusions 24, the number of protrusions are linearly arranged in a direction from the display area AA to the frame area SS. The embodiment of the present application does not limit the number of the protrusions 24. In one embodiment, the number of protrusions 24 is greater than or equal to three and less than or equal to six. Since the more the number of protrusions 24 is, the stronger the blocking ability against water and oxygen is, but at the same time, the size of the frame area SS also increases accordingly. By setting the number of protrusions 24 to 3-6, a compromise can be achieved between suppressing the intrusion of water and oxygen and reducing the size of the frame.

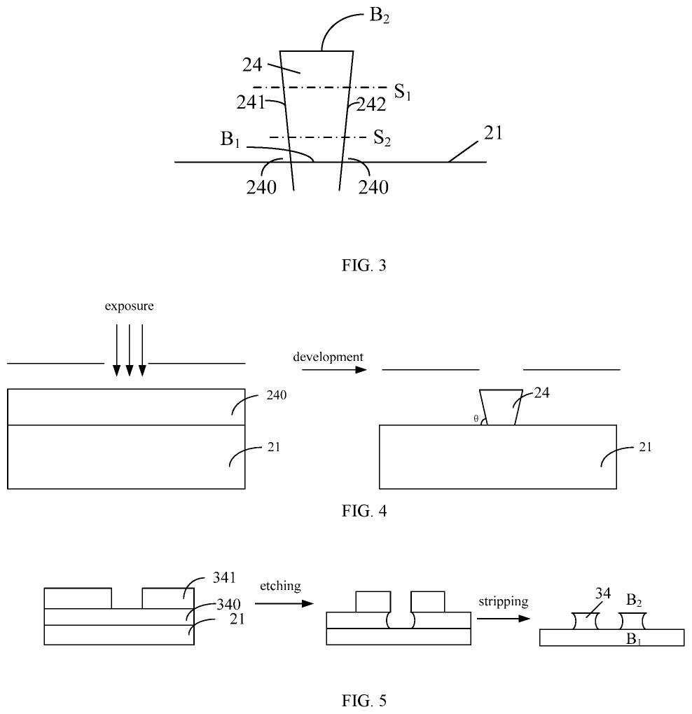

FIG. 3 is a schematic structural diagram of a protrusion provided by an embodiment of the present application. As shown in FIG. 2 and FIG. 3, the protrusion 24 surround the display area AA. The protrusion 24 includes a first cross section S₁ and a second cross section S₂ parallel to the array substrate 21 respectively, and the second cross section S₂ is located between the first cross section S₁ and the array substrate 21. The orthographic projection of the second cross section S₂ on the first cross section S₁ falls within the first cross section S₁. In this case, both the first sidewall 241 and the second sidewall 242 corresponding to the protrusion 24 include a concave area 240, thereby further improving the reliability of encapsulation.

Specifically, in one embodiment, as shown in FIG. 3, the protrusion 24 includes a first surface B₁ in contact with the array substrate 21 and a second surface B₂ provided opposite to the first surface B₁, and a width of the protrusion 24 gradually increases from the first surface B₁ to the second surface B₂. The width of the protrusion 24 refers to the vertical distance between a first intersection line of a cross section parallel to the array substrate 21 with the first side wall 241 of the protrusion 24 and a second intersection line of the cross section parallel to the array substrate 21 with the second side wall 242. The vertical distance is a length of the vertical line.

For example, as shown in FIG. 2 and FIG. 3, in the direction from the display area AA to the frame area SS, the cross section of the protrusion 24 is an inverted trapezoid. In this case, in one embodiment, the protrusion 24 is formed by photocuring a negative photoresist, where the negative photoresist is mainly a polymer containing epoxy groups, vinyl groups or episulfides. In one embodiment, the materials for forming the protrusion 24 include but are not limited to high molecular polymers such as epoxy resin, polymethyl methacrylate, polyimide, and the like.

The protrusion 24 with the inverted trapezoid cross-section can be prepared by the following steps. FIG. 4 is a schematic diagram of a manufacturing process of a protrusion provided by an embodiment of the present application. Referring to FIG. 4, specifically, an organic layer 240 is first deposited on an array substrate 21 by means of inkjet printing or silk-screen deposition, and then the organic layer 240 is patterned through exposure and development. For the negative-tone adhesive, the exposure degree decreases as the depth increases, that is, the deeper the position is, the easier it is to be developed. Therefore, the developed negative-tone adhesive forms the protrusion 24 with the inverted trapezoid cross-section.

In this embodiment, the included angle θ between the sidewall of the protrusion 24 with the inverted trapezoid cross-section and the array substrate 21 is greater than 0° and less than or equal to 60°.

In one embodiment, a frame area SS of the array substrate 21 includes a base substrate and an organic layer on the base substrate, the organic layer includes the protrusion 24, and the protrusion 24 is located on the surface of the organic layer away from the base substrate, that is, the protrusion 24 and the organic layer are integrally formed.

According to the display panel provided in this embodiment, the protrusion 24 with the inverted trapezoid cross-section is formed on the array substrate 21, and the process is simple and easy to implement.

In one embodiment, FIG. 5 is a schematic diagram of a manufacturing process of a protrusion provided by another embodiment of the present application. As shown in FIG. 5, the protrusion 34 includes a first surface B₁ contacting an array substrate 21 and a second surface B₂ provided opposite to the first surface B₁, and a width of the protrusion 34 decreases first and then increases from the first surface B₁ to the second surface B₂.

For example, as shown in FIG. 2 and FIG. 5, in the direction from the display area AA to the frame area SS, the cross section of the protrusion 34 is approximately I-shaped. In this case, in one embodiment, the protrusion 34 is formed of a metallic material. Since the adhesion between inorganic materials and inorganic materials is stronger than that between organic materials and inorganic materials, the use of metal to form the protrusion 34 can further improve adhesion between the protrusion 34 and isolation layer 23 compared to the use of organic materials to form the protrusion 34.

The protrusion 34 with the I-shaped cross-section can be prepared by the following steps. Referring to FIG. 5 of the present application, first, a metal layer 340 is deposited on the array substrate 21, and then a protective adhesive 341 is coated on the metal layer 340; then an anisotropic etching process is used, and the etching rate is controlled to increase first and then reduce as the etching depth increases, the protrusion 34 with the I-shaped cross-section is obtained; finally, the protective glue 341 is removed.

In one embodiment, the array substrate 21 includes a wiring layer, and the wiring layer includes the protrusion 34. In this case, the protrusion 34 and the circuit traces in the array substrate 21 are prepared synchronously, and the material that forms the protrusion 34 is the same as that of the circuit traces in the array substrate 21, such as titanium-aluminum-titanium alloy. Specifically, an opening is further opened at the position corresponding to the edge region SS of the array substrate 21 in the existing mask for preparing the wiring layer, so as to deposit a metal layer in the edge region SS, and then an anisotropic etching process is used to form the protrusion 34 with the I-shaped cross-section.

According to the display panel provided in this embodiment, the protrusion 34 with the I-shaped cross-section are formed on the array substrate 21, and the process is simple and easy to implement.

In one embodiment, the display panel 20 provided by any of the embodiments described above further includes a dam located in the frame area SS of the array substrate 21, as shown in FIG. 2. The dam is located on the side of the protrusion 24 close to the display area AA, and the isolation layer 23 further covers the dam. Specifically, the frame area SS of the array substrate 21 is provided with a first dam 251 and a second dam 252 sequentially surrounding the display area AA, and the protrusion 24 surround the second dam 252. The first dam 251 is used to define the boundary of the organic encapsulation layer 222, that is, theoretically, the boundary of the organic encapsulation layer 222 terminates at the side of the first dam 251 close to the display area AA. The second dam 252 is used to define the boundary of the first inorganic encapsulation layer 221 and the second inorganic encapsulation layer 223, that is, theoretically, the boundary of the first inorganic encapsulation layer 221 and the second inorganic encapsulation layer 223 terminates at the second dam 252. The first dam 251 and the second dam 252 can further block the intrusion of water and oxygen from the edge of the encapsulation structure 22.

It should be understood that due to a certain distance between the mask used in CVD film formation and the array substrate 21, the first inorganic encapsulation layer 221 and the second inorganic encapsulation layer 223 will cross the second dam 252, and a shadow area Q of the inorganic encapsulation layer is formed on a side of the second dam 252 away from the display area AA, and the protrusion 24 is located in the shadow area Q of the inorganic encapsulation layer. In this case, the protrusion 24 can function.

In one embodiment, as shown in FIG. 2, the display panel 20 further includes an encapsulation structure 22 stacked on the side of the isolation layer 23 away from the array substrate 21, an orthographic projection of the encapsulation structure 22 on the array substrate 21 and an orthographic projection of the isolation layer 23 on the array substrate 21 are coincident. The encapsulation structure 22 includes a first inorganic encapsulation layer 221, an organic encapsulation layer 222 and a second inorganic encapsulation layer 223 stacked on the array substrate 21 in sequence. In this case, the isolation layer 23 and the inorganic encapsulation layers in the encapsulation structure 22, that is, the first inorganic encapsulation layer 221 and the second inorganic encapsulation layer 223, share the same mask, thereby reducing the cost.

Specifically, the steps of forming the encapsulation structure 22 are as follows: a first inorganic encapsulation layer 221 is deposited on the display area AA and inside the second dam 252 by a CVD method, and the thickness may be 0.5 μm-1.5 μm. Since there is a certain distance between the mask and the array substrate 21, the first inorganic encapsulation layer 221 will cross the second dam 252. Then, an organic material is deposited inside the first dam 251 by inkjet printing, and after leveling and UV curing, an organic encapsulation layer 252 is formed, and the thickness of the organic encapsulation layer 252 may be 4-10 microns. Then, a second inorganic encapsulation layer 223 is again deposited on the organic encapsulation layer 222 within the second dam 252, and the thickness may be 0.5 micrometers to 1.5 micrometers. Likewise, since there is a certain distance between the mask and the array substrate 21, the second inorganic encapsulation layer 223 also crosses the second dam 252. The process of depositing the inorganic encapsulation layer multiple times together forms the shadow area Q of the inorganic barrier layer.

In one embodiment, as shown in FIG. 2, the frame area SS of the array substrate 21 includes a plurality of film layers stacked in sequence, and one end of the protrusion 24 close to the array substrate 21 is embedded in at least one of the plurality of film layers.

For example, in the display panel 20 shown in FIG. 2, the frame area SS of the array substrate 21 includes a base substrate and an organic layer on the base substrate, and the protrusion 24 is embedded in the organic layer. In this case, the edge area of the display panel 20 is flexible, the display panel is suitable for preparing a curved screen, and the protrusion 24 is embedded in the organic layer, which can avoid cracks at the position where the protrusion 24 contacts the organic layer during the process of forming the curved screen, thereby improving the reliability.

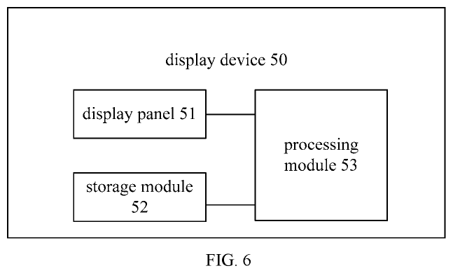

The present application also provides a display device. FIG. 6 is a structural block diagram of a display device according to an embodiment of the present application. The display device 50 may be a TV, a tablet battery, a mobile phone, or the like. As shown in FIG. 6, the display device 50 includes a display panel 51, a storage module 52 and a processing module 53.

The storage module 52 is used for storing media information. Specifically, the encoder performs analog-to-digital conversion according to coding rules, converts pixel information, such as pixel color, grayscale, contrast, etc., into binary numbers, and stores the binary numbers in the storage module 52.

The processing module 53 is connected to the display panel 51 and the storage module 52 for displaying media information on the display panel 51. Specifically, the processing module 53 controls the power supply of the power module to the other modules. After the power supply module supplies power, the processing module 53 accepts the image digital information stored in the storage module 52, performs digital-to-analog conversion on the image digital information, that is, converts the binary digital into original image information, and transmits it to the display panel for display.

The display device 50 provided according to the various embodiments of the present application and the display panel provided by any of the above embodiments are based on the same application concept. Details not described in the display device 50 can be found in the display panel, which will not be repeated here.

The foregoing description has been presented for the purposes of illustration and description. Furthermore, this description is not intended to limit the embodiments of the application to the forms disclosed herein. Although a number of example aspects and embodiments have been discussed above, those skilled in the art will recognize certain variations, modifications, changes, additions and sub-combinations thereof

What is claimed is:

1. A display panel, comprising:
an array substrate comprising a display area and a frame area surrounding the display area;
at least one protrusion located in the frame area, the protrusion comprising a first side wall on a side close to the display area and a second side wall on a side away from the display area, at least one of the first side wall and the second side wall comprising a concave area; and
an isolation layer stacked on one side of the array substrate and the protrusion, the at least one protrusion being located in an orthographic projection of the isolation layer on the array substrate.

2. The display panel according to claim 1, wherein the at least one protrusion comprises a plurality of protrusions surrounding the display area; the protrusion comprises a first cross section and a second cross section respectively parallel to the array substrate, the second cross section is located between the first cross section and the array substrate; and an orthographic projection of the second cross section on the first cross section falls within the first cross section.

3. The display panel according to claim 1, wherein the protrusion comprises a first surface in contact with the array substrate and a second surface opposite to the first surface; and a width of the protrusion gradually increases from the first surface to the second surface.

4. The display panel according to claim 3, wherein materials of the protrusion comprise an organic material.

5. The display panel according to claim 3, wherein a cross section of the protrusion in a direction perpendicular to the array substrate is an inverted trapezoid.

6. The display panel according to claim 1, wherein the protrusion comprises a first surface in contact with the array substrate and a second surface provided opposite to the first surface; and a width of the protrusion first decrease and then increase from the first surface to the second surface.

7. The display panel according to claim 6, wherein materials of the protrusion comprise metal.

8. The display panel according to claim 6, wherein a cross section of the protrusion in a direction perpendicular to the array substrate is I-shaped.

9. The display panel according to claim 1, wherein the frame region of the array substrate comprises a base substrate and an organic layer located on the base substrate, the organic layer comprises the protrusion, and the protrusion is located on a surface of the organic layer away from the base substrate.

10. The display panel according to claim 1, wherein the array substrate comprises a metal layer, and the metal layer comprises the at least one protrusion.

11. The display panel according to claim 1, wherein the frame area of the array substrate comprises a plurality of film layers stacked in sequence, and an end of the protrusion close to the array substrate is embedded in at least one of the plurality of film layers.

12. The display panel according to claim 1, wherein a height of the protrusion protruding from a surface of the array substrate on which the protrusion is disposed is equal to 1 micrometer or 10 micrometers, or between 1 micrometer and 10 micrometers.

13. The display panel according to claim 1, further comprising an encapsulation structure stacked on a side of the isolation layer away from the array substrate, an orthographic projection of the encapsulation structure on the array substrate and an orthographic projection of the isolation layer on the array substrate coincide.

14. The display panel according to claim 13, wherein the encapsulation structure comprises a first inorganic encapsulation layer, an organic encapsulation layer and a second inorganic encapsulation layer sequentially stacked on the array substrate.

15. The display panel according to claim 14, further comprising a dam member located in the frame area of the array substrate, the dam is located on a side of the protrusion close to the display area, and the isolation layer further covers the dam.

16. The display panel according to claim 15, wherein the dam member comprises a first dam and a second dam sequentially surrounding the display area, the protrusions surround the second dam, the first dam defines a boundary of the organic encapsulation layer, and the second dam defines a boundary of the first inorganic encapsulation layer and the second inorganic encapsulation layer.

17. The display panel according to claim 16, wherein a side of the second dam away from the display area forms a shadow area of the inorganic encapsulation layer, and the at least one protrusion is located in the shadow area of the inorganic encapsulation layer.
